(19) United States
(12) Patent Application Publication
(10) Pub. No.: US 2009/0136725 A1
(43) Pub. Date: May 28, 2009

(54) PROCESS FOR PRODUCING COPPER WIRING POLYIMIDE FILM, AND COPPER WIRING POLYIMIDE FILM

(76) Inventors: Hiroto Shimokawa, Ube (JP); Keita Bamba, Ichihara (JP)

Correspondence Address: KNOBBE MARTENS OLSON & BEAR LLP, 2040 MAIN STREET, FOURTEENTH FLOOR, IRVINE, CA, 92614, US

(21) Appl. No.: 12/294,421

(22) PCT Filed: Mar. 23, 2007
(86) PCT No.: PCT/JP2007/056076

§ 371 Date: Sep. 24, 2008

(30) Foreign Application Priority Data
Mar. 24, 2006 (JP) 2006-082238

(51) Int. Cl. H05K 3/18; H05K 1/09; H05K 3/38; B44C 1/22; B05D 5/12; B32B 15/08

(52) U.S. Cl. 428/209; 428/336; 427/118; 427/553; 156/344; 216/83

(57) ABSTRACT

There is disclosed a copper wiring polyimide film having wiring with ultra fine pitch and excellent in the linearity. The copper wiring polyimide film is produced by a process for producing a copper wiring polyimide film having a 20 to 45 μm-pitch copper wiring part by a semi-additive method using a copper foil laminated polyimide film with carrier. The process comprises (a) a step of providing a copper foil laminated film comprising a copper foil having a film side surface roughness Rz of not more than 1.0 μm and a thickness in the range of 0.5 to 2 μm laminated on a surface of a polyimide film, (b) a step of forming a plating resist pattern layer in which a wiring pattern having 20 to 45 μm pitch can be formed on the upper surface of the copper foil, (c) a step of conducting copper plating on the copper foil part exposed from the resist, (d) a step of removing the plating resist, and (e) a step of removing the copper foil exposed on the plating resist-removed part to expose a polyimide film.

### TECHNICAL FIELD

The present invention relates to a process for producing a copper wiring polyimide film having fine wirings by a semi-additive method using a copper foil laminated polyimide film with carrier.

### BACKGROUND ART

Since copper foil laminated polyimide films have excellent properties such as thinness and lightness in weight, they have been used for high-performance electronic devices, in particular, flexible printed circuit boards (FPC), tape automated bonding (TAB) or the like with high-density wirings which are suitable for reduction in size and weight. With the high density integration and fining of the electronic devices, wiring plates have been in demand to respond to high-density mounting.

As a method for manufacturing further microfine wiring pattern of a laminate of a synthetic resin film and a metal, there has been proposed a method for thinning a thickness of a metal layer (for example, refer to Patent Documents 1 to 3). Patent Document 1 discloses a metal-clad laminate having a metal layer formed on one side or both sides of the synthetic resin film, wherein the metal layer is a metal foil of not more than 5 microns. Specifically, there has been described that a circuit is formed with a copper foil having a thickness of 3 μm, and line and space of 25 μm and 25 μm (pitch 50 μm). Patent Document 2 discloses a copper-clad laminate comprising a copper foil having a thickness of 1 to 8 μm, an adhesive layer containing a thermoplastic polyimide resin as a main component, and a heat resistant film. The claims of Patent Document 3 discloses a metal-clad laminate in which a thermoplastic polyimide film is formed on at least one side of the non-thermoplastic polyimide film and a copper foil is laminated on a surface of the thermoplastic resin layer, wherein the thickness of the copper foil is not more than 5 μm.

However, if the etching pattern shape is not good and if fine pitches are further pursued, deterioration in insulating properties and reliability are expected. Accordingly, it is considered that there is a limitation on fine pitches simply by thinning the copper foil. Further, when the copper foil is excessively thinned, the reliability as a conductor is also considered to be lowered. Accordingly, a copper wiring polyimide film having a fine pattern, while having a appropriate thickness of the copper layer as a final product, has been demanded.

By the way, in Patent Documents 4 to 6, in order to improve the visibility of the wiring pattern, there has been described that the roughness on the side of the copper foil adhered to the film is made small (for example, Rz is not more than 1.0 μm (refer to Patent Documents 4 and 5)). However, there is suggested neither any application thereof to the copper foil with a thin thickness nor any use thereof for producing fine pitches.

Patent Document 1: International Publication No. WO2002/034509

Patent Document 2: Japanese Laid-open Patent Publication No. 2002-316386

Patent Document 3: Japanese Laid-open Patent Publication No. 2003-071984

Patent Document 4: Japanese Laid-open Patent Publication No. 2004-042579

Patent Document 5: Japanese Laid-open Patent Publication No. 2004-098659

Patent Document 6: International Publication (WO) No. WO03/096776

### DISCLOSURE OF THE INVENTION

### Problems to be Solved by the Invention

An object of the present invention is to provide a process for producing a copper wiring polyimide film having wiring with ultra fine pitch and excellent in the linearity by a semi-additive method using a copper foil laminated polyimide film with carrier.

### Means for Solving the Problems

The present invention relates to the following matters:

1. A process for producing a copper wiring polyimide film having a 20 to 45 μm-pitch copper wiring part by a semi-additive method using a copper foil laminated polyimide film with carrier, the process comprising steps of:
(a) providing a copper foil laminated film comprising copper foil(s) directly laminated on one side or both sides of a polyimide film; the copper foil having a surface roughness Rz of 1.0 μm or less in a side laminated to the polyimide film and a thickness in the range of 0.5 to 2 μm,
(b) forming a plating resist pattern layer capable of forming a wiring pattern having a 20 to 45 μm-pitch copper wiring part on the surface of the copper foil of the copper foil laminated film provided in the step (a); the plating resist pattern layer having an opening portion corresponding to the wiring pattern,
(c) carrying out copper plating on the copper foil part exposed from the opening,
(d) removing the plating resist pattern layer on the copper foil, and
(e) removing the copper foil exposed on a portion where the plating resist pattern layer has been removed, whereby exposing the polyimide film.
   2. The process according to the above item 1, wherein the step (a) comprises steps of
(a-1) providing a copper foil laminated polyimide film with carrier, wherein copper foil(s) has a surface roughness Rz of 1.0 μm or less in a side laminated to a polyimide film and a thickness in the range of 1 to 8 μm,
(a-2) peeling off the carrier foil from the copper foil laminated polyimide film, and
(a-3) optionally, thinning a thickness of the copper foil to the range of 0.5 to 2 μm by etching.
   3. The process according to the above item 1 or 2, in which the copper foil having a thickness in the range of 0.5 to 2 μm of the step (a) is a copper foil that has been subjected to etching treatment.
   4. The process according to any one of the above items 1 to 3, in which the step (b) comprises a step of forming a plating resist layer on a surface of the copper foil, a step of exposing to light through a photomask and a step of forming an opening portion of the plating resist pattern layer by development.
   5. The process according to any one of the above items 1 to 4, in which the step (e) is carried out by flash etching.
   6. The process according to any one of the above items 1 to 5, in which the thickness of the copper foil of the copper foil laminated polyimide film with carrier to be provided is in the range of 2 to 4 μm.
   7. The process according to any one of the above items 1 to 6, in which the polyimide film constituting the copper foil laminated polyimide film with carrier that is provided is obtained by laminating and integrating thermo-compression bonding polyimide layer(s) on one side or both sides of a high heat resistant aromatic polyimide layer.
   8. A copper wiring polyimide film which comprises a 20 to 45 μm-pitch copper wiring part and is produced by the process according to any one of the above items 1 to 7.
   9. A copper foil laminated polyimide film with carrier, comprising a polyimide film and a copper foil with carrier directly laminated on one side or both sides of the polyimide film, wherein the copper foil has a surface roughness Rz of 1.0 μm or less in the side laminated to the polyimide film and a thickness in the range of 1 to 8 μm.
   9. A copper foil laminated polyimide film with carrier, comprising a polyimide film and a copper foil with carrier directly laminated on one side or both sides of the polyimide film, wherein the copper foil has a surface roughness Rz of 1.0 μm or less in the side laminated to the polyimide film and a thickness in the range of 1 to 8 μm.

### EFFECT OF THE INVENTION

According to the present invention, it is possible to form an ultra fine pitch copper wiring excellent in the linearity by a semi-additive method using a copper foil laminated polyimide film with carrier. Accordingly, it is possible to produce an ultra fine pitch copper wiring which is excellent in long-term reliability (insulation between wirings) and also excellent in visibility on a polyimide film.

The copper wiring polyimide film produced according to the present invention can be used as a wiring substrate such as a flexible printed circuit board (FPC), tape automated bonding (TAB), COF and the like.

Furthermore, the copper foil laminated polyimide film with carrier prescribed in the present invention can be used for a process for producing a copper wiring polyimide film having a fine pattern. Thus, it is possible to form an ultra fine pitch copper wiring which is excellent in the linearity, and to obtain a substrate which is excellent in visibility of the wiring.

### BRIEF DESCRIPTION OF THE DRAWINGS

FIG. 1 is a process chart illustrating an example of the process for production of a one-sided copper wiring polyimide film by means of a semi-additive method using a one-sided copper foil laminated polyimide film with carrier.

FIG. 2 is a process chart illustrating an example of the process for production of a double-sided copper wiring polyimide film by means of a semi-additive method using a double-sided copper foil laminated polyimide film with carrier.

FIG. 3 is a process chart illustrating an example of the process for production until a through-hole is formed from a double-sided copper foil laminated polyimide film with carrier using a double-sided copper foil laminated polyimide film with carrier.

FIG. 4 is a view illustrating SEM observation (1,000 times) of a surface of the polyimide film having a 30 μm-pitch copper wiring obtained in Example 2.

FIG. 6 is a view illustrating SEM observation (1,000 times) of a surface of the polyimide film having a 30 μm-pitch copper wiring obtained in Example 3.

FIG. 6 is a view illustrating SEM observation (1,000 times) of a surface of the polyimide film having a 30 μm-pitch copper wiring obtained in Comparative Example 1.

### EXPLANATION OF THE REFERENCES

1: one-sided copper foil laminated polyimide film with carrier
2: polyimide film
3,3′: copper foil with carrier
4,4′: copper foil
5,5′: carrier
8,8′: polyimide film surface emerged after the copper foil is removed
9,9′: metal plating
10,10′: copper plating
17,17′: photoresist layer
21,21′: conductive film
100: double-sided copper foil laminated polyimide film with carrier
101: double-sided copper wiring polyimide film
102: double-sided copper wiring polyimide film subjected to metal plating on both sides

### BEST MODE FOR CARRYING OUT THE INVENTION

The process in the present invention will be illustrated with reference to the drawings.

### Embodiment 1

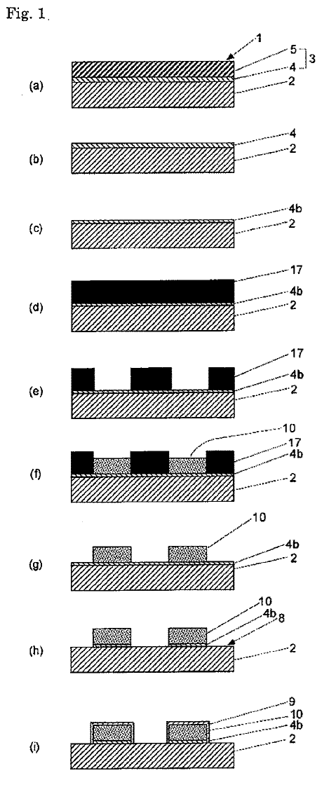

FIG. 1 illustrates an example of the process for production of a copper wiring polyimide film by means of a semi-additive method using a copper foil laminated polyimide film with carrier. In the present invention, a known semi-additive method can be used.

In the step (a) of the present invention, there is provided a copper foil laminated film having copper foil(s) directly laminated on one side or both sides of a polyimide film, wherein the copper foil has a surface roughness Rz of 1.0 μm or less in the side laminated to the polyimide film and a thickness in the range of 0.5 to 2 μm. This step (a) generally comprises substeps (a-1) to (a-3), that is, (a-1) a step of providing a copper foil laminated polyimide film with carrier, wherein copper foil(s) has a surface roughness Rz of 1.0 μm or less in a side laminated to a polyimide film and a thickness in the range of 1 to 8 μm, (a-2) a step of peeling off the carrier foil(s) from the copper foil laminated polyimide film, and (a-3) an optional step of thinning a thickness of the copper foil to the range of 0.5 to 2 μm by etching.

As shown in FIG. 1(a), the copper foil laminated polyimide film with carrier 1 provided in the step (a-1) has a structure in which a polyimide film 2 and a copper foil with carrier 3 are laminated. The copper foil with carrier 3 has a structure in which a copper foil 4 and a carrier 5 are laminated. Herein, the thickness of the copper foil is in the range of 1 to 8 μm, while surface roughness Rz of the laminated surface of the copper foil to the polyimide film is 1.0 μm or less.

Next, in the step (a-2), as shown in FIG. 1(b), the carrier foil 5 is peeled off from the copper foil laminated polyimide film with carrier 1 to obtain a copper foil laminated polyimide film wherein the copper foil and the polyimide film are directly laminated.

Then, in the step (a-3), as shown in FIG. 1(c), in order to thin the copper foil of the copper foil laminated polyimide film, etching is carried out as needed (half etching). According to this step, the thickness of the copper foil is thinned to the range of 0.5 to 2 μm (in FIG. 1, a thinned copper foil is represented by a symbol of 4b). However, when the thickness of the copper foil of the provided copper foil laminated polyimide film with carrier is within this range, the step of half etching can be omitted. Usually, it is preferable to thin the copper foil by 0.5 μm or more by means of half etching.

For half etching of the copper foil, a well-known method can be appropriately selected and carried out. For example, there can be used a method comprising dipping the copper foil laminated polyimide film into a well-known half etching solution or a method comprising spraying a half etching solution using a spray apparatus, to further thin the copper foil. As the half etching solution, the well-known ones can be used, and examples thereof include solutions in which hydrogen peroxide is mixed with sulfuric acid or solutions comprising sodium persulfate aqueous solution as a main ingredient. Examples thereof include DP-200 manufactured by Ebara-Udylite Co., Ltd. and ADEKA TEC CAP manufactured by Asahi Denka Kogyo K.K.

The next step (b) is a step of forming a plating resist pattern layer on the upper surface of the copper foil of the copper foil laminated film provided in the step (a). In this step, in general, as shown in FIG. 1(d), a photoresist layer 17 is formed on the upper part of the copper foil of the copper foil laminated polyimide film, and subsequently, as shown in FIG. 1(e), the photoresist layer is exposed to light using the mask of a wiring pattern, followed by developing and removing a portion to be the wiring pattern. The copper foil to be the wiring pattern site is emerged from the opening section obtained by developing and removing the resist. Since the resist opening portion (resist removed part) corresponds to the wiring pattern, the opening portion is determined to have patterns, such as opening line width, pitch and the like, that enable the formation of a 20 to 45 μm-pitch copper wiring part.

The photoresist may be a negative type and a positive type, and may be a liquid form, a film form or the like. Typically, the photoresist is formed on the copper foil by heat laminating the negative dry film-type resist, or applying and drying the positive liquid-type resist. In the case of the negative type, an unexposed site is removed by developing; on the other hand, in the case of the positive type, an exposed site is removed by developing. The thicker resist may be easily obtained for the dry film-type resist. For example, SPG-152 manufactured by Asahi Kasei Co., Ltd. and RY-3215 manufactured by Hitachi Chemical Co., Ltd. are exemplified as the negative dry film-type photoresist.

Furthermore, as the method to develop and remove the photoresist layer, known chemical(s) for developing and removing the photoresist layer can be appropriately selected. For example, a photoresist layer can be developed and removed by spraying sodium carbonate aqueous solution (1% etc.) and the like.

In the next step (c), as shown in FIG. 1(f), a copper plating layer 10 is formed on the upper part of the copper foil emerged from an opening where the photoresist layer 17 is removed. As the copper plating step, a known copper plating condition can be appropriately selected. For example, an exposed site of the copper foil is washed with an acid or the like, and electrolytic copper plating is carried our at a current density of 0.1 to 10 A/dm² with the copper foil as a cathode electrode in a solution typically comprising copper sulfate as a predominant constituent, whereby a copper layer is formed. As the electrolytic solution, there can be used a solution in which 180 to 240 g/l of copper sulfate, 45 to 60 g/l of sulfuric acid and 20 to 80 g/l of chlorine ion, and thiourea, dextrin or thiourea and molasses as additives are added.

In the next step (d), as shown in FIG. 1(g), the photoresist layer 17 used as a plating resist is removed to expose the copper foil covered with the plating resist pattern layer.

In the next step (e), as shown in FIG. 1(h), the copper foil exposed to a portion where the aforementioned plating resist pattern layer is removed is removed to expose a polyimide film surface 8. The thin copper foil is removed usually by flash etching. In this way, the copper wiring polyimide film can be produced.

As a flash etching solution used for flash etching, the well-known ones can be used, and examples thereof include solutions in which hydrogen peroxide is mixed with sulfuric acid or solutions comprising aqueous solutions of diluted ferric chloride as a main ingredient, for example, FE-830 manufactured by Ebara Densan Ltd. and AD-305E manufactured by Asahi Denka Kogyo K.K. Although here the copper of the circuit part (wiring) is dissolved when removing the thin copper foil, no substantial defect is made because the amount of etching necessary to remove the thin copper foil is small.

Furthermore, as shown in FIG. 1(i), there is formed a metal plating layer 9 in which at least a part of the copper wiring of the copper wiring polyimide film is plated by tin plating or the like as needed, whereby a copper wiring polyimide film subjected to metal plating can be produced.

### Embodiment 2

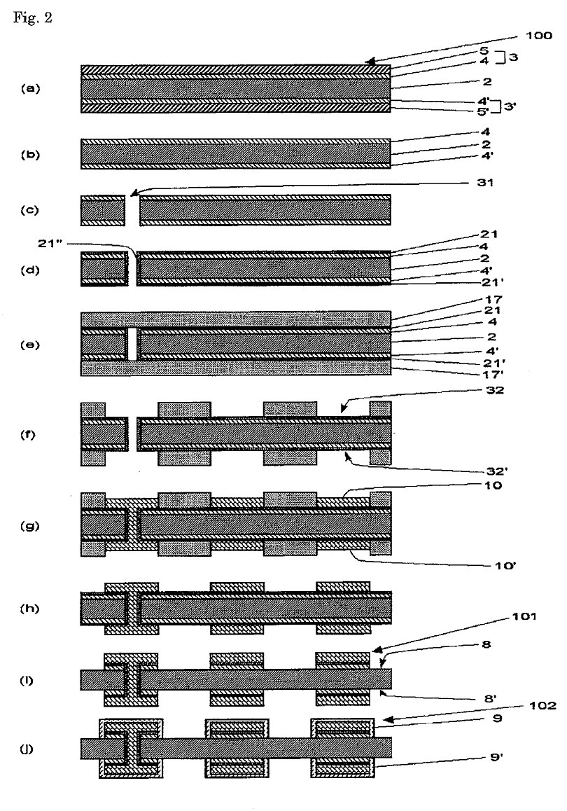

In this embodiment, FIG. 2 illustrates an example of the process for forming a circuit by means of a semi-additive method using a polyimide film laminated with sheets of copper foil with carrier on both sides.

In the step (a-1), as shown in FIG. 2(a), there is provided a polyimide film 100 laminated with sheets of copper foil with carrier on both sides. In this copper foil laminated polyimide film 100, a copper foil with carrier 3, a polyimide film 2 and a copper foil with carrier 3′ are laminated in this order, while copper foils with carrier 3, 3′ are respectively a laminate of copper foils 4, 4′ and carriers 5, 5′. Herein, the thickness of the copper foil is in the range of 1 to 8 μm, while surface roughness Rz of the laminated side of the copper foil to the polyimide film is 1.0 μm or less.

In the next step (a-2), as shown in FIG. 2(b), the carrier foil 5 and the carrier foil 5′ are peeled off from the double-sided copper foil laminated polyimide film with carrier 100 to obtain a double-sided copper foil laminated polyimide film in which the copper foil 4, the polyimide film and the copper foil 4′ are directly laminated.

In the next step (a-3), as shown in FIG. 2(c), etching (half etching) is carried out in order to thin the copper foils (4, 4′) of the double-sided copper foil laminated polyimide film. Thereafter, a through-hole 31 is formed through a portion of electrolytic copper foils of both sides of the double-sided copper foil laminated polyimide film and the polyimide layer by using a laser or the like. A plurality of through-holes may be formed. The order of hole-forming processing and half etching may be reversed. By half etching, the thickness of the copper foil can be thinned to the range of 0.5 to 2 μm.

Then, as shown in FIG. 2(d), conductive films 21, 21′, 21″ are formed on the polyimide surface of the through-hole 31 of the copper foil laminated polyimide film and on the copper foils (4,4′), so that the copper foil 4 and the copper foil 4′ are electrically connected. The thickness of the conductive film and the copper foil in total is preferably also in the range of 0.5 to 2 μm.

In the next step (b), a plating resist pattern layer capable of forming a wiring pattern having a 20 to 45 μm-pitch copper wiring part is formed on the surface of the copper foil of the copper foil laminated film provided in the step (a), wherein, the plating resist pattern layer having an opening corresponding to the wiring pattern. In this step, as shown in FIG. 2(e), photoresist layers (17, 17′) are formed on the upper part of the copper foils (4, 4′) of the copper foil laminated polyimide film, and subsequently, as shown in FIG. 2(f), the photoresist layer is exposed to light using the mask of a wiring pattern, followed by developing and removing a portion to be the wiring pattern. A plurality of copper foil portions (32, 32′) to be the wiring pattern are emerged from the opening section where the resist is developed and removed. Since the resist opening portion (resist removed part) corresponds to the wiring pattern, the opening portion is determined to have patterns, such as opening line width, pitch and the like, that enable the formation of a 20 to 45 μm-pitch copper wiring part. The photoresist which can be used herein is the same as that described in Embodiment 1.

In the next step (c), as shown in FIG. 2(g), copper plating layers (10, 10′) are formed on the upper part of the copper foil portions (32, 32′) emerged from the opening where the photoresist layers (17, 17′) are removed.

In the next step (d), as shown in FIG. 2(h), the photoresist layer 17 used as a plating resist is removed to expose the copper foil covered with the plating resist pattern layer.

In the next step (e), as shown in FIG. 2(i), the copper foil exposed to a portion in which the plating resist pattern layer is removed, to expose the polyimide film. The thin copper foil is removed usually by flash etching. In this way, the double-sided copper wiring polyimide film 101 can be produced. In FIG. 2(i), the potions in which copper of the double-sided copper wiring polyimide film 101 is removed by flash etching are represented by symbols of 8 and 8′. The copper wirings on both surfaces formed on the outer part of the through-hole of the double-sided copper wiring polyimide film 101 are electrically connected. As a flash etching solution used for flash etching, there can be used the same solutions as those described in Embodiment 1.

Furthermore, as shown in FIG. 2w), there are formed metal plating layers (9, 9′) in which at least a part of the copper wiring of the double-sided copper wiring polyimide film 101 is plated such as tin plating or the like as needed, whereby a double-sided copper wiring polyimide film 102 subjected to metal plating can be produced.

### Embodiment 3

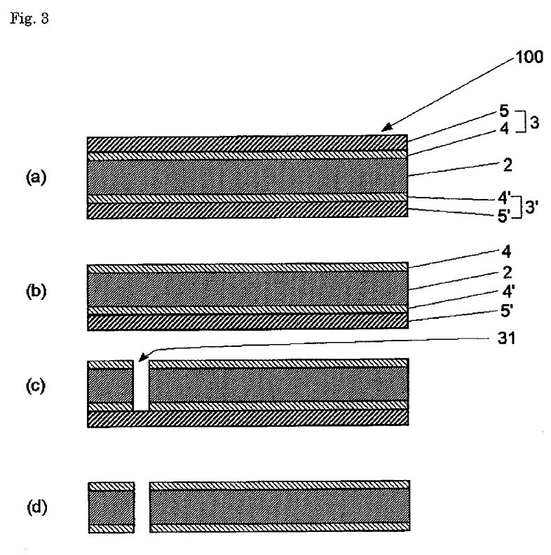

Another example of the process (FIGS. 2(a) to (c)) for forming a through-hole 31 in the first part of Embodiment 2 will be described by FIGS. 3(a) to (d).

As shown in FIG. 3(a), a polyimide film 100 having sheets of copper foil with carrier laminated on both surfaces is provided in the same manner as in Embodiment 2.

As shown in FIG. 3(b), only a carrier foil 5 on one surface is peeled off from the double-sided copper foil laminated polyimide film with carrier 100 to obtain a double-sided copper foil laminated polyimide film in which a copper foil 4 and a polyimide film, and a copper foil 4′ and a carrier 5′ are directly laminated.

As shown in FIG. 3(c), a through-hole 31 is formed through a portion of electrolytic copper foils on both sides of the double-sided copper foil laminated polyimide film and the polyimide layer by using a laser or the like. In this case, a through-hole may also be formed through the carrier 5′. Furthermore, a through-hole may not be formed through the copper foil 4′ and the carrier 5′ so as to form a blind via hole. A plurality of through-holes or blind via holes may be formed. The carrier 5′ at a state in FIG. 3(b) or 3(c) may be effectively used as a support of the film or a protector during processing of the through-hole.

Then, as shown in FIG. 3(d), the carrier 5′ is peeled off, and as needed etching (half etching) is further carried out in order to thin the copper foils (4, 4′) of the double-sided copper foil laminated polyimide film.

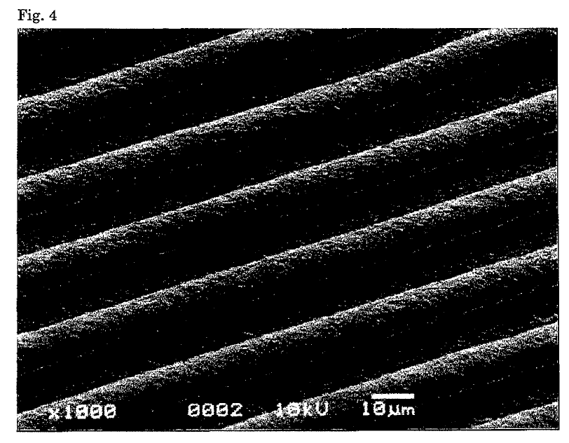

In the subsequent steps, the same process is employed as in the step of FIG. 4(d) and subsequent figures of Embodiment 2.

In the aforementioned steps of Embodiments 1 to 3, roll to roll processing may be used for continuous operation.

In Embodiments 2 and 3, where not particularly mentioned, the same manner as in Embodiment 1 is employed, but the change relating a through-hole will be described.

The through-hole or the blind via hole can be formed, for example, by removing through a portion of the copper foil of either one side or both sides and the polyimide film at the same time using a UV-YAG laser, before or after peeling off the carrier foil either on one side or both sides. Alternatively, the copper foil on the portion of the polyimide film to be holed is removed beforehand by etching etc, and then the polyimide film may be removed by an irradiation with a carbon dioxide laser to form a blind via hole, or a hole penetrating both surfaces may be formed by punching or drilling.

Furthermore, in Embodiments 2 and 3, when a wiring part is formed by a pattern plating method (step (c)), the formation of via hole, by electrically connecting through the hole using an electrolytic-plating method, is preferably carried out at the same time. In this step, after inside of the through-hole or the blind via hole is desmeared, a conductive film is formed inside of the through-hole or the blind via hole by the so-called DPS (Direct Plating System) method forming a palladium-tin film using a palladium-tin colloid catalyst. Thereafter, a copper layer is formed in the hole and on the circuit site on both surfaces by the following steps: (i) applying or laminating a photosensitive-type dry film plating resist on both sides of the copper foil, (ii) exposing to light through the photomask of a wiring pattern, (iii) spraying 1% sodium carbonate aqueous solution etc and developing to remove the plating resist layer at the site to be the wiring pattern and the site to be the electrically connected hole, (iv) washing an exposed site of the thin copper foil with acid etc, and (v) typically carrying out electrolytic copper plating at a current density of 0.1 to 10 A/dm² with the thin copper foil as a cathode electrode in a solution typically containing copper sulfate as a main agent. This state is a structure illustrated in FIG. 2(g).

Herein, the RISERTRON DPS system manufactured by Ebara-Udylite Co., Ltd. can be exemplified as the DPS step. Herein, a surface-treatment with an aqueous solution comprising monoethanolamine as a main agent makes a condition in which the palladium-tin colloid catalyst readily adsorbs. Subsequently, the surface of the thin copper foil having readily-adsorbing property by treatment is removed with a soft etching solution to inhibit formation of a palladium-tin film on the copper foil surface, and ensure adhesion strength of the copper foil surface and electrolytic plating. It is dipped into sodium chloride, hydrochloric acid and so on. After these steps, a Pd—Sn film is formed in the activating step comprising dipping into a palladium-tin colloid liquid. A reducing agent may be added to an alkaline accelerator bath used for activation during final activation in an alkaline accelerator bath containing sodium carbonate, potassium carbonate and copper ion, and an acid accelerator bath containing sulfuric acid. Examples of the reducing agent which can be added include, for example, aldehydes such as formaldehyde, acetaldehyde, propionaldehyde and benzaldehyde, and catechol, resorcin, ascorbic acid and so on. The alkaline accelerator bath to which the reducing agent is added preferably comprises sodium carbonate, potassium carbonate and copper ion. By the method already described, a low resistant film composed of Pd—Sn can be obtained.

A specific example of the method to form a circuit by a semi-additive method using the polyimide film in which the copper foil with carrier is laminated on its both surfaces is illustrated. From a rolled-up polyimide film in which sheets of copper foil with carrier are laminated on both sides, a 10.5×25 cm rectangular sample is cut out and the double-sided carrier foil is peeled off. The double-sided electrolytic copper foil and the polyimide layer are subjected to laser processing with a UV-YAG LASER [a product of Electro Scientific Industries, Inc. (ESI, Inc.), Model: 5320, Wavelength: 355 μm] to form a through-hole for forming a through-hole VIA. Using DP-200 manufactured by Ebara-Udylite Co., Ltd. as a half etching solution, the copper foil is dipped at 25° C. for 2 minutes so that the thickness of the copper foil becomes 1 μm. Laser smear in the hole or the like is removed by the RISERTRON DS (desmear) process manufactured by Ebara-Udylite Co., Ltd., and then a conductive film is formed by the RISERTRON DPS process of the same Ebara-Udylite Co., Ltd. A dry film-type negative type photoresist (SPG-152, a product of Asahi Kasei Co., Ltd.) is laminated on the DPS-treated copper foil by a heat roll at 110° C., and then the photoresist is exposed to light except a portion where a circuit is intended to be formed (wiring pattern) and the portion to be the through-hole, and unexposed resist is spray-developed with 1% sodium carbonate aqueous solution and removed at 30° C. for 20 seconds. After degreasing and acid-washing the exposed site of the thin copper foil and inside the through-hole in which a conductive film is formed, electrolytic copper plating is conducted in a copper sulfate plating bath with the thin copper foil as a cathode electrode at a current density of 2 A/dm² at 25° C. for 30 minutes, and pattern plating of copper plating with 10 μm in thickness inside the conductive film-formed through-hole is carried out. Subsequently, when the resist layer is removed off by spray treatment with 2% sodium hydroxide aqueous solution at 42° C. for 15 seconds, and then the thin-film copper in an unnecessary portion is removed by spray treatment with a flash etching solution (AD-305E, a product of Asahi Denka Kogyo K.K.) at 30° C. for 30 seconds, a polyimide film having a 30 μm-pitch copper wiring on its both surfaces is obtained.

The copper wiring polyimide film formed by the process of the present invention comprises a copper wiring portion of from 20 to 45 μm pitch, preferably from 22 to 42 μm pitch, further preferably from 24 to 40 μm pitch, more preferably from 25 to 361 μm pitch and particularly preferably from 26 to 30 μm pitch. Herein, the term pitch refers to a total width of the copper wiring and a space between copper wirings. The 30 μm pitch refers, for example, to a copper wiring of 15 μm and a space of 15 μm between copper wirings.

In case of the copper wiring polyimide film, metal plating such as tin plating or the like can be further carried out on at least a part of the copper wiring.

In the explanation of the aforementioned process, the copper foil laminated film provided in the step (a) is a copper foil laminated film wherein copper foil(s) is directly laminated on one side or both sides of the polyimide film, and wherein the copper foil has

(1) a surface roughness Rz of 1.0 μm or less, further preferably 0.8 μm or less and more preferably 0.7 μm or less in the side laminated to polyimide film and (2) a thickness in the range of 0.5 to 2 μm, preferably in the range of 0.7 m to 2 μm, further preferably in the range of 0.8 to 1.8 μm and particularly preferably in the range of 0.8 to 1.5 μm, preferably formed by etching treatment. Etching treatment is generally performed by the aforementioned steps (a-1) to (a-3). This copper foil laminated film is very useful for the production of an ultra fine pitch copper wiring polyimide film, as described above and illustrated in Examples.

The one-sided or double-sided copper foil laminated polyimide film with carrier to be used in the above step (a-1) of the present invention will be described below. In the copper foil laminated polyimide film with carrier, as described above, copper foil (s) with carrier is directly laminated on one side or both sides of the polyimide film, wherein the copper foil has a surface roughness Rz of 1.0 μm or less in the side laminated to polyimide film and a thickness in the range of 1 to 8 μm.

In the copper foil with carrier, the thickness of the carrier is not particularly limited, but it may be selected such that the thin copper foil can be reinforced; and the thickness of the carrier is preferably from 10 to 40 μm, further preferably from 10 to 35 μm and more preferably from 10 to 18 μm. The thickness of the copper foil 4 is preferably from 1 to 8 μm, further preferably from 1 to 6 μm, more preferably from 2 to 5 μm and more preferably from 2 to 4 μm, while the surface roughness Rz of the copper foil in the side laminated to polyimide film is preferably 1.0 μm or less, further preferably 0.8 μm or less and more preferably 0.7 μm or less.

It is possible to obtain a wiring substrate having excellent adhesion strength even after heating at 150° C. for 168 hours, by using the laminate of the copper foil with carrier 3 and polyimide, in particular preferably a multi-layer polyimide, which is obtained by laminating and integrating a thermo-compression bonding polyimide film on one side or both sides of a high heat resistant aromatic polyimide layer.

As the copper foil of the copper foil with carrier, there can be used copper, copper alloy and the like, such as electrolytic copper foil, rolled copper foil or the like. Rolled copper foil can be particularly preferably used.

The material of the carrier of the copper foil with carrier is not particularly limited, but it may be selected so that it can be attached to the copper foil, function so as to reinforce and protect the copper foil, be readily peeled off from the copper foil and withstand a lamination temperature for laminating polyimide. For example, aluminum foil, copper foil, resin foil with metal-coated surface and the like can be used.

In the case of the electrolytic copper foil with carrier foil, since copper components are electrodeposited on the carrier foil surface to form an electrolytic copper foil, the carrier foil needs to have at least conductivity.

The carrier foil that can be used is those that travel through a series of manufacturing steps, and keep juncture with the copper foil layer at least until completion of producing the copper foil laminated polyimide film, and facilitate handling.

The carrier foil, which may be used, is removed by peeling off the carrier foil after laminating the copper foil with carrier foil to the polyimide foil, or can be removed by an etching method after laminating the copper foil with a carrier foil to the polyimide film.

In the copper foil with carrier, those obtained by bonding the carrier and the copper foil by an adhesive agent of a metal or ceramic can be suitably used as they are excellent in heat resistance.

For the copper foil with carrier, at least one side to be laminated with the polyimide film is surface-treated, such as roughening treatment, anti-corrosion treatment, heat resistant treatment, chemical resistant treatment or the like, with at least one metal selected from Ni, Cr, Co, Zn, Sn and Mo or an alloy comprising at least one of these metals. Furthermore, the surface can be silane-coupling treated.

The polyimide film of the copper foil laminated polyimide film with carrier 1 can be directly laminated with the copper foil of the copper foil with carrier, and examples thereof include a polyimide film used as a base material of electronic parts such as printed wiring boards, flexible printed circuit boards, TAB tapes, COF substrates and the like; and polyimides obtained from acid components and diamine components constituting these polyimide film, or polyimides comprising acid components and diamine components constituting these polyimide film.

As the polyimide film 2, its linear expansion coefficient (50 to 200° C.) is preferably close to the linear expansion coefficient of the copper foil to be laminated with the polyimide film, and the linear expansion coefficient (50 to 200° C.) of the polyimide film is preferably from 0.5×10⁻⁵ to 2.8×10⁻⁵ cm/cm/° C.

As the polyimide film, that having heat shrinkage ratio of not more than 0.05% is preferably used due to small heat distortion.

The polyimide film can be used in the form of a mono-layer film, a multi-layer film laminated with two or more layers and a sheet.

The thickness of the polyimide film is not particularly limited, but preferably it may be in the range such that lamination of the polyimide film and the copper foil with carrier can be done without any problem, manufacturing and handling can be done, and the copper foil can be sufficiently supported. It is preferably from 1 to 500 μm, more preferably from 2 to 300 μm, further preferably from 5 to 200 μm, more preferably from 7 to 175 μm, and particularly preferably 8 to 100 μm.

As the polyimide film, substrates surface-may be treated by such as corona discharge treatment, plasma treatment, chemical roughening treatment, physical roughening treatment and the like at least on one side of the substrate.

For the polyimide film of the copper foil laminated polyimide film with carrier, there can be used a multi-layer polyimide film having at least two or more layers comprising a thermo-compression bonding polyimide layer (a) which can be directly laminated with the copper foil, on one side or both sides of a heat resistant polyimide layer (b) by compression or thermo-compression.

Furthermore, for the copper foil laminated polyimide film with carrier, there can be used those obtained by laminating the heat resistant polyimide layer (b) and the copper foil with carrier, through the thermo-compression bonding polyimide layer (a), by compression or thermo-compression.

Specific examples of the heat resistant polyimide layer (b) and the polyimide film include polyimide films such as product name: Upilex (S or R) (a product of Ube Industries, Ltd.), product name: Kapton (a product of DuPont-TORAY Co., Ltd.), product name: Apical (a product of Kaneka Corp.) and the like; or polyimide obtained from acid components and diamine components constituting these films.

The polyimide film can be produced by a well-known method, and for example, for a mono-layer polyimide film, the following methods can be utilized:

(1) a method involving flow-casting or applying a solution of a poly(amic acid) as a polyimide precursor on a support, and imidizing it; and

(2) a method involving flow-casting or applying a polyimide solution on a support, and then, if necessary, heating it.

A two or more-layer polyimide film can be obtained by the following methods:

(3) a method involving flow-casting or applying a solution of a poly(amic acid) as a polyimide precursor on a support, and furthermore flow-casting or applying successively a solution of a poly(amic acid) as a polyimide precursor for the second or later layers on the upper surface of the previous poly(amic acid) layer flow-casted or applied on the support, and imidizing them;

(4) a method involving simultaneously flow-casting or applying solutions of a poly(amic acid) for two or more layers as a polyimide precursor on a support, and imidizing them;

(5) a method involving flow-casting or applying a polyimide solution on a support, and furthermore successively flow-casting or applying a polyimide solution for the second or later layers on the upper surface of the previous polyimide film flow-casted or applied on the support, and, if necessary, heating them;

(6) a method involving simultaneously flow-casting or applying polyimide solutions for two or more layers on a support, and, if necessary, heating them; and

(7) a method involving laminating two or more polyimide films obtained by the above methods (1) to (6) directly or through an adhesive agent.

When the copper foil with carrier and the polyimide film are laminated, a heating machine, a compression machine or a thermo-compression machine may be used, and preferably a heating or compression condition is appropriately selected depending on materials to be used. Although the production process is not particularly limited as long as continuous or batch laminating is employable, it is preferably carried out continuously by using a roll laminator, a double-belt press or the like.

As an example of the production method of the copper foil laminated polyimide film with carrier, the following method is exemplified. That is, a lengthy copper foil with carrier (length of 200 to 2,000 m), a lengthy polyimide film and a lengthy copper foil with carrier are piled in three layers in this order, and furthermore a protection film is piled outside if needed. They are preferably pre-heated at about 150 to 250° C., particularly at a temperature higher than 150° C. and 250° C. or lower for about 2 to 120 seconds in line immediately before introducing in the machine by using a pre-heater such as a hot-air blower or an infrared heating machine. By using a pair of compression-bonding rolls or a double-belt press, the three-ply of copper foil with carrier/polyimide film/copper foil with carrier is thermally bonded under pressure, wherein a temperature in a heating and compression-bonding zone of the compression-bonding rolls or the double-belt press is within a range of higher by 20° C. or more than a glass transition temperature of polyimide and below 400° C., particularly higher by 30° C. or more than the glass transition temperature and below 400° C. In particular, in the case of a double-belt press, the laminate is successively cooled while being pressed in a cooling zone. The laminate is suitably cooled to a temperature lower by 20° C. or more, particularly lower by 30° C. or more than the glass transition temperature of the polyimide to complete lamination, and rewound in a roll form. Thus, the roll-form one-sided or double-sided copper foil laminated polyimide film with carrier can be produced.

The pre-heating of the polyimide film before thermo-compression bonding is effective to prevent the occurrence of defective appearance by laminate's foaming after thermo-compression bonding or foaming when soaking in a solder bath during formation of electronic circuits due to moisture contained in the polyimide. Thus, decreasing in production yield can be prevented.

The double-belt press can perform heating to high temperature and cooling down while applying pressure, and a hydrostatic type one using a heat carrier is preferable.

In the production of the double-sided copper foil layer polyimide film with carrier foil, lamination is carried out preferably at a drawing rate of 1 m/min or more by thermo-compression bonding and cooling under pressure using a double-belt press. Thus obtained double-sided copper foil laminated polyimide film with carrier is continuously long and has a width of about 400 mm or more, particularly about 500 mm or more, and high adhesion strength (the peel strength of the metal foil and the polyimide film is not less than 0.7 N/mm, and the retention rate of the peel strength is not less than 90% after heating treatment at 150° C. for 168 hours), and further has good appearance so that substantially no wrinkles are observed on the copper foil surface. Thus, the double-sided copper foil laminated polyimide film with carrier can be obtained.

In order to mass-produce the double-sided copper foil laminated polyimide film with carrier with good appearance, while one or more combinations of the thermo-compression bonding polyimide film and the copper foil with carrier are being supplied, protectors are placed between top-surface layer at both sides and the belts (i.e., two sheets of protectors), and these together are preferably bonded and laminated by thermo-compression bonding and cooling under pressure.

For the protector, its material is not particularly limited for use as long as it is non-thermo-compression bonding and has a good surface smoothness, and the preferred examples thereof include metal foil, particularly copper foil, stainless foil, aluminum foil, and high heat resistant polyimide film (Upilex S, manufactured by Ube Industries, Ltd., Kapton H manufactured by DuPont-TORAY Co., Ltd.) and the like having about 5 to 125 μm in thickness.

In the thermo-compression bonding polyimide film, as the heat resistant polyimide layer (b), it is preferable to use a heat resistant polyimide constituting a base film which can be used as a tape material of electronic parts such as printed wiring boards, flexible printed circuit boards, TAB tapes, COF substrates and the like.

In the thermo-compression bonding polyimide film, the heat resistant polyimide used for the heat resistant polyimide layer (layer b) may be selected from those having at least one of the following properties, or those having at least two of the following properties {i.e., the combination of 1) and 2), 1) and 3) or 2) and 3)}, and particularly from those having all of the following properties:

1) in the case of polyimide film alone, a glass transition temperature is 300° C. or higher, preferably 330° C. or higher, and further preferably, a glass transition temperature is undetectable;

2) in the case of polyimide film alone, a linear expansion coefficient (50 to 200° C.) (MD) is preferably close to a thermal expansion coefficient of a metal foil such as a copper foil laminated on a heat resistant resin substrate, and when using a copper foil as a metal foil, a thermal expansion coefficient of the heat resistant resin substrate is preferably from 5×10⁻⁶ to 28×10⁻⁶ cm/cm/° C., more preferably from 9×10⁻⁶ to 20×10⁻⁶ cm/cm/C and further preferably from 12×10⁻⁶ to 18×10⁻⁶ cm/cm/° C.; and

3) in the case of polyimide film alone, a tensile modulus (MD, ASTM-D882) is 300 kg/mm² or more, preferably 500 kg/mm² or more and further preferably 700 kg/mm² or more.

As the heat resistant polyimide of the heat resistant polyimide layer (b), there can be used polyimide obtained from the combination of:

(1) an acid component containing at least one selected from 3,3′,4,4′-biphenyltetracarboxylic dianhydride, pyromellitic dianhydride and 1, 4-hydroquinone dibenzoate-3,3′,4,4-tetracarboxylic dianhydride, and preferably an acid component containing these acid components in an amount of at least not less than 70 mole %, further preferably not less than 80 mole % and more preferably not less than 90 mole %; and

(2) diamine component containing at least one selected from p-phenylene diamine, 4,4′-diaminodiphenyl ether, m-tolidine and 4,4′-diamino benzanilide, and preferably a diamine component containing these diamine components in an amount of at least not less than 70 mole %, further preferably not less than 80 mole % and more preferably not less than 90 mole %.

As the combination of the acid component and the diamine component constituting the heat resistant polyimide layer (b), there can be exemplified those obtained by containing the following combinations:

1) 3,3′,4,4′-biphenyltetracarboxylic dianhydride, and p-phenylene diamine or (p-phenylene diamine and 4,4-diaminodiphenyl ether),

2) 3,3′,4,4′-biphenyltetracarboxylic dianhydride and pyromellitic dianhydride, and p-phenylene diamine or (p-phenylene diamine and 4,4-diaminodiphenyl ether),

3) pyromellitic dianhydride, and p-phenylene diamine and 4,4-diaminodiphenyl ether, and

4) 3,3′,4,4′-biphenyltetracarboxylic dianhydride and p-phenylene diamine, as main ingredient components (not less than 50 mole % in the total 100 mole %), They are used as materials of electronic parts such as printed wiring boards, flexible printed circuit boards, TAB tapes and the like, and they are preferred because they have excellent mechanical properties over a wide temperature range, long-term heat resistance, excellent resistance to hydrolysis, a high heat decomposition initiation temperature, small heat shrinkage ratio and linear expansion coefficient, and excellent flame retardancy.

As the acid component capable of obtaining heat resistant polyimide of the heat resistant polyimide layer (b), there can be used an acid dianhydride component such as 2,3,3′,4′-biphenyltetracarboxylic dianhydride, 3,3′,4,4′-benzophenonetetracarboxylic dianhydride, bis(3, 4-dicarboxyphenyl)ether dianhydride, bis(3,4-dicarboxyphenyl)sulfide dianhydride, bis(3,4-dicarboxyphenyl)sulfone dianhydride, bis(3, 4-dicarboxyphenyl)methane dianhydride, 2,2-bis(3, 4-dicarboxyphenyl)propane dianhydride, 2, 2-bis(3, 4-dicarboxyphenyl)-1,1,1,3,3,3-hexafluoropropane dianhydride, 2,2-bis[(3,4-dicarboxyphenoxy)phenyl]propane dianhydride or the like, in addition to the acid components illustrated above, in the ranges in which the characteristics of the present invention are not impaired.

As the diamine component capable of obtaining heat resistant polyimide of the heat resistant polyimide layer (b), there can be used a diamine component such as m-phenylene diamine, 3,4′-diaminodiphenyl ether, 3,3′-diaminodiphenyl sulfide, 3,4′-diaminodiphenyl sulfide, 4,4′-diaminodiphenyl sulfide, 3,3′-diaminodiphenyl sulfone, 3,4′-diaminodiphenyl sulfone, 4,4′-diaminodiphenyl sulfone, 3, 3′-diaminobenzophenone, 4,4′-diaminobenzophenone, 3,4-diaminobenzophenone, 3,3′-diaminodiphenyl methane, 4,4′-diaminodiphenyl methane, 3,4′-diaminodiphenyl methane, 2,2-di(3-aminophenyl)propane, 2,2-di(4-aminophenyl)propane and the like, in addition to the diamine components illustrated above, in the ranges in which the characteristics of the present invention are not impaired.

As the thermo-compression bonding polyimide layer (layer a), there can be used known polyimide having a property capable of heat-seal bonding (thermo-compression bonding property) a tape material of electronic parts such as printed wiring boards, flexible printed circuit boards, TAB tapes, COF substrates and the like or the heat resistant polyimide and the copper foil, or having a property capable of performing heat-seal bonding under pressure (thermo-compression bonding property).

The thermo-compression bonding polyimide for the thermo-compression bonding polyimide layer (layer a) is preferably polyimide having thermo-compression bonding property capable of performing lamination with a copper foil at a temperature in the range from a glass transition temperature of the thermo-compression bonding polyimide to 400° C.

As the thermo-compression bonding polyimide of the thermo-compression bonding polyimide layer (layer a) for the thermo-compression bonding polyimide film, there can be used those having at least one property below, those having at least two properties below {i.e., the combination of 1) and 2); 1) and 3); or 2) and 3)}, those having at least three properties below {i.e., the combination of 1), 2) and 3); 1), 3) and 4); 2), 3) and 4); 1), 2) and 4); or the like}, and particularly those having all properties below:

1) the thermo-compression bonding polyimide layer (layer a) has a peel strength between the copper foil and “layer a”, or the copper foil and the thermo-compression bonding polyimide film of 0.7 N/mm or more, and the retention ratio of a peel strength after heat treatment at 150° C. for 168 hours is 90% or more, further 95% or more and particularly 100% or more;

2) its glass transition temperature is from 130 to 330° C.

3) its tensile modulus is from 100 to 700 Kg/mm²; and

4) its linear expansion coefficient (50 to 200° C.) (MD) is from 13×10⁻⁶ to 30×10⁻⁶ cm/cm/° C.

As a fusion bondable polyimide of the thermo-compression bonding polyimide layer (layer a), there can be used polyimide obtained from:

(1) an acid component containing at least one component selected from acid dianhydrides such as 3,3′,4,4′-biphenyltetracarboxylic dianhydride, 2,3,3′,4-biphenyltetracarboxylic dianhydride, pyromellitic dianhydride, 3,3′,4,4′-benzophenonetetracarboxylic dianhydride, bis(3,4-dicarboxyphenyl)ether dianhydride, bis(3,4-dicarboxyphenyl)sulfide dianhydride, bis(3,4-dicarboxyphenyl)sulfone dianhydride, bis(3,4-dicarboxyphenyl)methane dianhydride, 2,2-bis(3,4-dicarboxyphenyl)propane dianhydride, 1,4-hydroquinone dibenzoate-3,3′,4,4′-tetracarboxylic dianhydride and the like, and preferably an acid component containing these acid components in an amount of at least not less than 70 mole %, further preferably not less than 80 mole % and more preferably not less than 90 mole %, and

(2) a diamine component containing at least one component selected from diamines such as 1,3-bis(4-aminophenoxy)benzene, 1,3-bis(3-aminophenoxy)benzene, 1,4-bis(4-aminophenoxy)benzene, 3,3′-diaminobenzophenone, 4,4′-bis(3-aminophenoxy)biphenyl, 4,4′-bis(4-aminophenoxy)biphenyl, bis [4-(3-aminophenoxy)phenyl]ketone, bis[4 (4-aminophenoxy)phenyl]ketone, bis [4-(3-aminophenoxy)phenyl]sulfide, bis[4-(4-aminophenoxy)phenyl] sulfide, bis[4-(3-aminophenoxy)phenyl] sulfone, bis[4-(4-aminophenoxy)phenyl] sulfone, bis[4-(3-aminophenoxy)phenyl]ether, bis[4-(4-aminophenoxy)phenyl] ether, 2, 2-bis[4-(3-aminophenoxy)phenyl]propane, 2,2-bis[4-(4-aminophenoxy)phenyl]propane and the like as a diamine component, and preferably a diamine component containing these diamine components in an amount of at least not less than 70 mole %, further preferably not less than 80 mole % and more preferably not less than 90 mole %.

As the combination of the acid component and the diamine component capable of obtaining polyimide of the thermo-compression bonding polyimide layer (layer a), there can be used polyimide obtained from:

(1) an acid component containing at least one component selected from acid dianhydrides such as 3,3′,4,4′-biphenyltetracarboxylic dianhydride and 2,3,3′,4′-biphenyltetracarboxylic dianhydride, and preferably an acid component containing these acid components in an amount of at least not less than 70 mole %, further preferably not less than 80 mole % and more preferably not less than 90 mole %; and

(2) a diamine component containing at least one component selected from diamines such as 1,3-bis(4-aminophenoxy)benzene, 1, 3-bis(3-aminophenoxy)benzene, 4,4′-bis(3-aminophenoxy)biphenyl, bis [4-(3-aminophenoxy)phenyl]sulfone, bis [4-(3-aminophenoxy)phenyl]ether, 2, 2-bis[4-(3-aminophenoxy)phenyl]propane, 2,2-bis[4-(4-aminophenoxy)phenyl]propane and the like as a diamine component, and preferably a diamine component containing these diamine components in an amount of at least not less than 70 mole %, further preferably not less than 80 mole % and more preferably not less than 90 mole %.

As the diamine component capable of obtaining polyimide of the thermo-compression bonding polyimide layer (layer a), there can be used a diamine component such as m-phenylene diamine, 3,4′-diaminodiphenyl ether, 3,3′-diaminodiphenyl sulfide, 3,4′-diaminodiphenyl sulfide, 4,4′-diaminodiphenyl sulfide, 3,3′-diaminodiphenyl sulfone, 3,4′-diaminodiphenyl sulfone, 4,4′-diaminodiphenyl sulfone, 3, 3′-diaminobenzophenone, 4,4′ diaminobenzophenone, 3,4′-diaminobenzophenone, 3,3′-diaminodiphenyl methane, 4,4′-diaminodiphenyl methane, 3,4′-diaminodiphenyl methane, 2,2-di(3-aminophenyl)propane, 2,2-di(4-aminophenyl)propane and the like, in addition to the diamine components illustrated above, in the ranges in which the characteristics of the present invention are not impaired.

Both of the polyimide of the heat resistant polyimide layer (layer b) and the polyimide of the fusion bondable polyimide layer (layer a) can be synthesized by a known method such as random polymerization or block polymerization, or the method including combining a plurality of polyimide precursor solutions or polyimide solutions synthesized beforehand, mixing the plurality of solutions and then mixing under reaction conditions to give a uniform solution.

Both of the polyimide of the heat resistant polyimide layer (layer b) and the polyimide of the fusion bondable polyimide layer (layer a) can be produced by a method in which acid components and diamine components are reacted in an organic solvent at a temperature of about not more than 100° C., further not more than 80° C. and further 0 to 60° C., particularly at a temperature of from 20 to 60° C., for about 0.2 to 60 hours to give a polyimide precursor solution, and then using this polyimide precursor solution as a dope liquid, a thin film of the dope liquid is formed, and its solvent is evaporated and removed from the thin film and at the same time the polyimide precursor is imidized.

Furthermore, in the case that polyimide excellent in solubility is used, the organic solvent solution of the polyimide can be obtained by heating the polyimide precursor solution at 150 to 250° C., or adding an imidization agent at not more than 150° C., particularly reacting at a temperature of from 15 to 50° C., and followed by evaporating the solvent after imide-cyclizing, or followed by precipitation in a poor solvent to give powder, and dissolving the powder in the organic solution.

When polymerization reaction of the polyimide precursor in solution is carried out, the concentration of the total monomers in an organic polar solvent may be suitably selected depending on the purpose of use or the purpose of production. For example, for the polyimide precursor solution of the heat resistant polyimide layer (layer b), the concentration of the total monomers in the organic polar solvent is preferably from 5 to 40% by mass, further preferably form 6 to 35% by mass and particularly preferably from 10 to 30% by mass. For the polyimide precursor solution of the fusion bondable polyimide layer (layer a), the concentration of the total monomers in the organic polar solvent is preferably from 1 to 15% by mass and particularly from 2 to 8% by mass.

When polymerization reaction of the polyimide precursor solution is carried out, the solution viscosity may be suitably selected depending on the purpose of use (coating, flow casting or the like) or the purpose of production. The solution of a poly(amic acid) (polyimide precursor) preferably has the rotating viscosity, measured at 30° C., from about 0.1 to 5,000 poises, particularly from about 0.5 to 2,000 poises and further preferably from about 1 to 2,000 poises, from the viewpoint of workability of handling this solution of a poly(amic acid). Accordingly, the aforementioned polymerization reaction is preferably carried out to the extent that the generated poly(amic acid) exhibits the above viscosity.

For the fusion bondable polyimide layer (layer a), a polyimide precursor solution may be produced in the above method, and an additional organic solvent may be added for dilution.

For both of the polyimide of the heat resistant polyimide layer (layer b) and the polyimide of the fusion bondable polyimide layer (layer a), the almost-equimolar amounts of diamine components and tetracarboxylic dianhydrides, the amounts thereof with a little excess amount of diamine components or the amounts thereof with a little excess amount of acid components are reacted in an organic solvent so that a polyimide precursor solution (it may be partially imidized as long as uniform solution condition is obtained) can be obtained.

Both of the polyimide of the heat resistant polyimide layer (layer b) and the polyimide of the fusion bondable polyimide layer (layer a) may be synthesized by adding dicarboxylic anhydrides, such as phthalic anhydride and its substituted compound, hexahydrophthalic anhydride and its substituted compound, succinic anhydride and its substituted compound and so on, particularly phthalic anhydride, in order to cap the amine terminal.

For both of the polyimide of the heat resistant polyimide layer (layer b) and the polyimide of the fusion bondable polyimide layer (layer a), the amount of diamines used in an organic solvent (as the number of moles of amino groups) is from 0.95 to 1.05, particularly from 0.98 to 1.02 and particularly from 0.99 to 1.01 based on the total number of moles of acid anhydrides (as the total number of moles of acid anhydride groups of tetra acid dianhydrides and dicarboxylic acid anhydrides). When dicarboxylic acid anhydrides are used, individual components are reacted in such a ratio that the amount of dicarboxylic acid anhydrides as the ratio to the mole of acid anhydride groups of tetra acid dianhydrides is not more than 0.05.

For the purpose to restrict gelation of the polyimide precursor, a phosphorus-base stabilizer, for example, triphenyl phosphite, triphenyl phosphate and so on can be added within a range of 0.01 to 1% of the solid (polymer) concentration during polymerization of the poly(amic acid).

In addition, for the purpose to promote imidization, a basic organic compound may be added to the dope liquid. For example, there may be used imidazole, 2-imidazole, 1,2-dimethylimidazole, 2-phenylimidazole, benzimidazole, isoquinoline, substituted-pyridine and so on as an imidization promoter in a proportion of 0.05 to 10 weight % and particularly 0.1 to 2 weight % based on the poly(amic acid). Since these compounds can form a polyimide film at a relatively low temperature, they may be used in order to avoid insufficient imidization.

Furthermore, for the purpose to stabilize adhesion strength, organic aluminum compounds, inorganic aluminum compounds or organic tin compounds may be added to the solution of a poly(amic acid), particularly for the fusion bondable polyimide. For example, aluminum hydroxide, aluminum triacetylacetonate and the like may be added at 1 ppm or more and particularly at 1 to 1,000 ppm as an aluminum metal to the poly(amic acid).

As for the organic solvent used for production of the poly(amic acid), there can be exemplified N-methyl-2-pyrrolidone, N,N-dimethylformamide, N, N-dimethylacetamide, N,N-diethylacetamide, dimethylsulfoxide, hexamethylphosphoramide, N-methylcaprolactam, cresols and the like. These organic solvents may be used alone or more than two kinds together.

The polyimide film having thermo-compression bonding property can be obtained preferably by a method (i) or (ii), i.e.:

(i) by the coextrusion-flow-casting film formation method (also being simply referred to as multi-layer extrusion method), the dope liquid of the heat resistant polyimide layer (layer b) and the dope liquid of the thermo-compression bonding polyimide layer (layer a) are laminated, dried and imidized to obtain a multi-layer polyimide film, or

(ii) the dope liquid of the heat resistant polyimide layer (layer b) is flow-cast on a support, and dried to give a self-supporting film (gel film), and next, on one side or both sides thereof, the dope liquid of the thermo-compression bonding polyimide layer (layer a) is applied, dried and imidized to give a multi-layer polyimide film.

For the coextrusion method, there may be used a well-known method, for example, a method described in the Japanese Laid-open Patent Publication No. H03-180343 (Japanese Kokoku Patent Publication No. H07-102661).

An embodiment of the production of a three-layer thermo-compression bonding polyimide film having thermo-compression bonding properties on both sides is illustrated.

The solution of a poly(amic acid) for the heat resistant polyimide layer (layer b) and the solution of a poly(amic acid) for the thermo-compression bonding polyimide layer (layer a) are supplied to a three-layer extrusion molding die by a three-layer coextrusion method so that the thickness of the heat resistant polyimide layer (layer b) is 4 to 45 μm and the thickness of the thermo-compression bonding polyimide layer (layer a) on both sides is 3 to 10 μm in total, and cast on a support and this is flow-cast and applied on a smooth support surface such as a stainless mirror surface and a stainless belt surface, and at 100 to 200° C., the polyimide film A as a self-supporting film can be obtained in a semi-cured state or a dried state before the semi-curing.

For the polyimide film A as a self-supporting film, if a flow-casted film is treated at a temperature higher than 200° C., some defects tend to occur such as decrease in adhesiveness during production of the polyimide film having thermo-compression bonding property. This semi-cured state or the state before the semi-curing means a self-supporting state by heating and/or chemical imidization.

The polyimide film A as a self-supporting film obtained is heated at a temperature of not lower than the glass transition temperature (Tg) of the thermo-compression bonding polyimide layer (layer a) and not higher than degradation-occurring temperature, preferably a temperature of from 250 to 420° C. (surface temperature measured by a surface thermometer) (preferably heating at this temperature for 0.1 to 60 minutes), dried and imidized. Thus, the polyimide film having the thermo-compression bonding polyimide layer (layer a) on both sides of the heat resistant polyimide layer (layer b) is produced.

In the polyimide film A as a self-supporting film obtained, a solvent and generated water remain preferably at about 20 to 60% by mass and particularly preferably from 30 to 50% by mass. This self-supporting film is preferably heated up for relatively short period when it is heated-up to a drying temperature. For example, a heating rate is preferably not less than 10° C./min. When drying, by increasing the tension applied to the self-supporting film, the linear expansion coefficient of the polyimide film A thus finally obtained is reduced.

Then, following the above-mentioned drying step, the self-supporting film is continuously or intermittently dried and heat-treated, in a condition in which at least a pair of side edges of the self-supporting film is fixed by a fixing equipment capable of continuously or intermittently moving together with the self-supporting film, at a high temperature higher than the drying temperature, preferably within a range of 200 to 550° C. and particularly preferably within a range of 300 to 500° C. preferably for 1 to 100 minutes and particularly 1 to 10 minutes. The polyimide film having thermo-compression bonding property on both sides may be formed by sufficiently removing the solvent or the like from the self-supporting film and at the same time sufficiently imidizing the polymer consisting of the film so that the contents of volatile components consisting of organic solvents and generated water in the polyimide film to be finally obtained is preferably not more than 1 weight %.

The fixing equipment of the self-supporting film preferably used herein is, for example, equipped with a pair of belts or chains having a plurality of pins or holders at even intervals, along both side edges in the longitudinal direction of the solidified film supplied continuously or intermittently, and is able to fix the film while the pair of belts or chains are continuously or intermittently moved with movement of the film. In addition, the fixing equipment of the above solidified film may be able to extend or shrink the film under heat treatment with a suitable elongation percentage or shrinkage ratio in a lateral direction or a longitudinal direction (particularly preferably from about 0.5 to 5% of elongation percentage or shrinkage ratio).

Incidentally, the polyimide film having thermo-compression bonding property on both sides having particularly excellent dimensional stability may be obtained by heat-treating the polyimide film having thermo-compression bonding property on both sides produced in the above step again under low or no tension of preferably not higher than 4N and particularly preferably not higher than 3N at a temperature of 100 to 400° C. preferably for 0.1 to 30 minutes. In addition, the thus-produced lengthy polyimide film having thermo-compression bonding property on both sides may be rewound in a roll form by an appropriate known method.

The heating loss of the above self-supporting film refers to a value obtained by the following equation from the weight W1 measured before drying and the weight W2 measured after drying when the object film is dried at 420° C. for 20 minutes.

Heating Loss(% by mass)={(W1−W2)/W1}×100

Furthermore, the imide conversion ratio of the above self-supporting film is obtained by the method using a Karl Fischer's moisture meter as described in the Japanese Laid-open Patent Publication No. H09-316199.

A fine inorganic or organic additive may be added to the self-supporting film inside or surface layer thereof as needed. As the inorganic additive, there can be exemplified a particle-like or platelet-like inorganic filler. As the organic additive, there can be exemplified polyimide particles, particles of a thermosetting resin or the like. The amount and shape (size, aspect ratio) are preferably selected depending on the purpose of use.

Heating treatment can be performed by using various known equipments such as a hot air furnace, an infrared furnace or the like.

The one-sided or double-sided copper wiring polyimide film of the present invention can be used as a wiring material for a flexible printed circuit board (FPC), tape automated bonding (TAB), COF and the like.

### EXAMPLES

The present invention is now illustrated in detail below with reference to Examples. However, the present invention is not restricted to these Examples.

Physical properties were evaluated according to the following method.

1) Glass transition temperature (Tg) of polyimide film: It was determined from a peak tan δ value by a dynamic viscoelasticity method (tensile method; frequency: 6.28 rad/sec; temperature rising rate: 10° C./min).

2) Linear expansion coefficient (50 to 200° C.) of polyimide film: An average linear expansion coefficient at 20 to 200° C. was measured by a TMA method (tensile method; temperature rising rate: 5° C./min).

3) Peel strength of metal foil laminated polyimide film (as made), peel strength of polyimide film and adhesive film: In accordance with JIS-C6471, a lead with 3 mm in width (a sample piece) defined in the same test method was prepared, and for nine test pieces each from metal of roll inner side and roll outer side, the 90° peel strength was measured at a cross-head speed of 50 mm/min. For the polyimide film and the copper foil laminated polyimide film, its peel strength is an average of nine values. For the laminate of the polyimide film and the adhesive sheet, its peel strength is an average of three values. If the thickness of the metal foil is less than 5 μm, it is electroplated by 20 μm of thickness, and the measurement is carried out. (Roll inner means a peel strength of inside of the metal foil laminated polyimide film rewound, and roll outer means a peel strength of outside of the metal foil laminated polyimide film rewound.).

4) Inter-wiring insulation resistance, volume resistance of metal foil laminated polyimide film: They were measured in accordance with JIS-C6471.

5) Mechanical properties of polyimide film
Tensile strength: It was measured in accordance with ASTM-D882 (cross-head speed: 50 mm/min).
Elongation percentage: It was measured in accordance with ASTM-D882 (cross-head speed: 50 mm/min).
Tensile modulus: It was measured in accordance with ASTM-D882 (cross-head speed: 5 mm/min).

6) MIT bending resistance (polyimide film): A test piece with 15 mm in width across the full width was cut out in accordance with JIS-C6471, and the bending times were measured until the polyimide film was fractured at a curvature radius of 0.38 mm, a load of 9.8 N, a bending rate of 175 times/min and left/right flexing angle of 135 degrees.

### Reference Example 1

### Production Example of Thermo-Compression Bonding Multi-Layer Polyimide Film

In N-methyl-2-pyrrolidone, p-phenylenediamine (PPD) and 3,3′,4,4′-biphenyltetracarboxylic dianhydride (s-BPDA) were added in a molar ratio of 1,000:998 such that a monomer concentration was 18% (weight %, the same hereinafter). The resulting mixture was reacted at 50° C. for 3 hours to obtain a solution of a poly(amic acid) (a dope for heat resistant polyimide) having a solution viscosity of about 1,500 poises at 25° C.

On the other hand, to N-methyl-2-pyrrolidone, 1,3-bis(4-aminophenoxy)benzene (TPE-R) and 2,3,3′,4′-biphenyltetracarboxylic dianhydride (a-BPDA) were added in a molar ratio of 1,000:1,000 such that a monomer concentration was 22%. Further, triphenyl phosphate in 0.1% relative to the monomer weight was added thereto, and then the resulting mixture was continuously reacted at 5° C. for 1 hour to obtain a dope of a solution of a poly(amic acid) (a dope for thermo-compression bonding polyimide) having a solution viscosity of about 2,000 poises at 25° C.

The dope for heat resistant polyimide and the dope for thermo-compression bonding polyimide were flow-casted on a metal support by using a film-forming equipment provided with a three-layer extrusion die (multi-manifold type die) while varying a thickness of the three-layer extrusion die and continuously dried under hot air at 140° C. to form a solidified film. After peeling off this solidified film from the support, the solvent was removed by gradually heating from 200° C. to 450° C. in a heating furnace, and imidization was carried out, and the resulting long three-layer extrusion polyimide film was wound onto a wind-up roll. The resulting three-layer extrusion polyimide film exhibited the following physical properties.

(Thermo-compression bonding multi-layer polyimide film)
Thickness configuration: 3 μm/9 μm/3 μm (total 15 μm)
Coefficient of static friction: 0.37.
Tg of thermo-compression bonding polyimide: 240° C. (dynamic viscoelasticity method, peak tan δ value, the same hereinafter)
Tg of heat resistant polyimide: not less than 340° C.
Linear expansion coefficient (50 to 200° C.): 18 ppm/° C. (TMA method)
Tensile strength, elongation percentage: 460 MPa, 90% (ASTM-D882)
Tensile modulus: 7080 MPa (ASTM-D882)
MIT bending resistance: not fractured until 100,000 times

### Example 1

### Copper Foil Laminated Polyimide Film with Carrier

Rolled-up copper foil with carrier manufactured by Nippon Denkai Ltd. (YSNAP-3S: carrier thickness 18 μm, copper thickness 3 μm, polyimide-side surface roughness Rz of copper foil 0.65 μm), the thermo-compression bonding polyimide film which was pre-heated by hot air at 200° C. for 30 seconds in line immediately before a double-belt press, and the polyimide film (UPILEX-S: 25 μm) manufactured by Ube Industries, Ltd. were laminated by successively thermo-compression bonding and cooling at a heating zone temperature (the highest heating temperature: 330° C.) and a cooling zone temperature (the lowest cooling temperature: 180° C.) of the double-belt press, continuously with a compression-bonding pressure of 40 kg/cm² and a compression-bonding time of 2 minutes, which was then wound around a wind-up roll to form a copper foil laminated polyimide film with carrier (width: 540 mm, length: 1,000 m) on one side.

Adhesion strength between the copper foil and the polyimide film of the obtained copper foil laminated polyimide film with carrier was 1.2 N/mm.

### Example 2

### Production of Copper Foil Laminated Polyimide Film and Copper Wiring Polyimide Film by Semi-Additive Method

Using the rolled-up one-sided copper foil laminated polyimide film with carrier obtained in Example 1, a sample of 10.5×25 cm rectangular was cut out, and the carrier foil was peeled off.

Using DP-200 manufactured by Ebara-Udylite Co., Ltd. as a half etching solution, the copper foil of the copper foil laminated polyimide film from which the carrier foil was peeled off was dipped at 25° C. for 2 minutes so that the thickness of the copper foil became 1 μm.

After laminating a dry film-type negative photoresist (SPG-152 manufactured by Asahi Kasei Co., Ltd.) on the half-etching treated copper foil by a thermal roll at 110° C., a site other than the portion where circuit (wiring pattern) was intended to be formed was exposed to light, and unexposed resist was spray-developed with 1% sodium carbonate aqueous solution at 30° C. for 20 seconds and removed. After degreasing and acid-washing the bare site of the thin copper foil, electrolytic copper plating was conducted in a copper sulfate plating bath with the thin copper foil as a cathode electrode at a current density of 2 A/dm² at 25° C. for 30 minutes, and pattern plating of copper plating with 10 μm in thickness was carried out.

Subsequently, after peeling off the resist layer by spray treatment with a 2% sodium hydroxide aqueous solution at 42° C. for 15 seconds, the thin copper foil in an unnecessary site was removed by spray treatment with a flash etching solution (AD-305E manufactured by Asahi Denka Kogyo K.K.) at 30° C. for 30 seconds to obtain a polyimide film having a 30 μm-pitch copper wiring.

A SEM (magnification: 1,000 times) image of the surface of the resulting copper wiring polyimide film is shown in FIG. 4. It could be confirmed that the polyimide film surface where the copper foil was removed between copper wirings was clean, and the circuit was formed into highly straight-line at the bottom portion of the copper wiring.

Furthermore, the copper wiring of the obtained polyimide film having a copper wiring could be clearly viewed through the polyimide film from the opposite side of the polyimide film having a copper wiring.

### Example 3

### Production of Copper Foil Laminated Polyimide Film and Copper Wiring Polyimide Film by Semi-Additive Method

A copper foil laminated polyimide film with carrier was produced in the same manner as in Example 1, except that a copper foil with carrier (YSNAP-2S: carrier thickness 18 μm, copper thickness 2 μm, polyimide-side surface roughness Rz of copper foil 0.65 μm) manufactured by Nippon Denkai, Ltd. was used as the copper foil with carrier in Example 1. Using this copper foil laminated polyimide film with carrier, a copper wiring polyimide film was produced in the same manner as in Example 2. Herein, at the time of half etching, the time was adjusted such that the thickness of the copper foil became 1 μm.

The produced copper wiring polyimide film was dipped into a tin plating solution (LT-34H, a product of Rohm and Haas Co.) and tin plating was conducted on the surface of the copper wiring. A SEM image of the tin-plated surface of the copper wiring polyimide film is illustrated in FIG. 5. It could be confirmed that the straightness of wiring was high and the surface of the polyimide film was also clean.

Long-Term Stability Test:

Using the copper wiring polyimide film in Example 3, the electrical reliability test was conducted. In the electrical reliability test, a DC voltage of 52V was applied in an environment of 85° C. 85% RH to measure the resistance. The initial resistance value was 10¹³Ω, and the value of 10¹³Ω was maintained even when 1,000 hours were exceeded.

### Comparative Example 1

A copper foil laminated polyimide film with carrier was produced in the same manner as in Example 1, except that a copper foil with carrier (YSNAP-3B: carrier thickness 18 μm, copper thickness 3 μm, surface roughness Rz of copper foil 1.29 μm) manufactured by Nippon Denkai, Ltd. was used instead of the copper foil with carrier (YSNAP-SS: carrier thickness 18 μm, copper thickness 3 μm, surface roughness Rz of copper foil 0.65 μm) manufactured by Nippon Denkai, Ltd. used in Examples 1 and 2. Apolyimide film having a 30 μm-pitch copper wiring was obtained in the same manner as in Example 2.

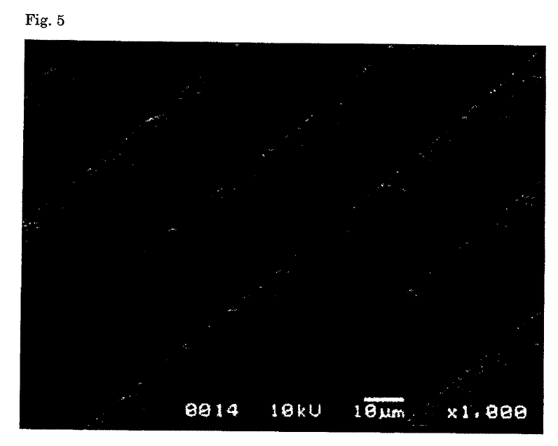

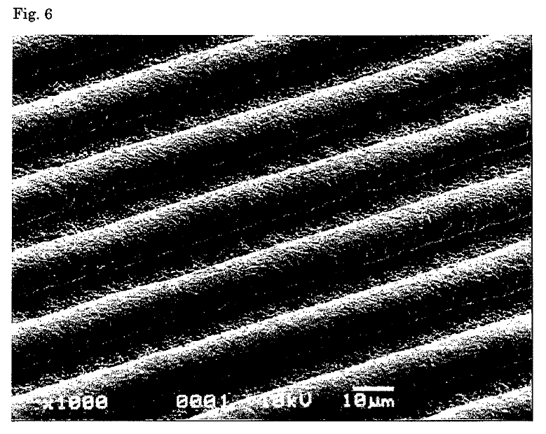

With respect to the obtained polyimide film having a copper wiring, an image of the surface of the copper wiring and the polyimide film where the copper foil was removed between wirings, taken by SEM (magnification: 1,000 times), is shown in FIG. 6.

While the copper wiring of the obtained polyimide film having a copper wiring could be viewed through the polyimide film from the opposite side of the polyimide film having a copper wiring, it could not be viewed as clearly as viewed in Examples 2 and 3.

When comparing FIGS. 4 to 6, in Comparative Example (FIG. 6), the polyimide film surface where the copper foil was removed was rough as compared to FIGS. 4 and 5, and the linearity of the copper wiring bottom portion was lowered than FIGS. 4 and 5.

When the electrical reliability test was carried out for the copper wiring polyimide film produced in Example 2 in the same conditions as the copper wiring polyimide film of Example 3, that is, a DC voltage of 52V was applied in an environment of 85° C. 85% RH to measure the resistance, the initial resistance value was 10¹³Ω and it was considered that the value of 10¹³Ω was maintained even when 1,000 hours were exceeded.

1. A process for producing a copper wiring polyimide film having a 20 to 45 μm-pitch copper wiring part by a semi-additive method using a copper foil laminated polyimide film with carrier, the process comprising steps of:
(a) providing a copper foil laminated film comprising copper foil(s) directly laminated on one side or both sides of a polyimide film; the copper foil having a surface roughness Rz of 1.0 μm or less in a side laminated to the polyimide film and a thickness in the range of 0.5 to 2 μm,
(b) forming a plating resist pattern layer capable of forming a wiring pattern having a 20 to 45 μm-pitch copper wiring part on the surface of the copper foil of the copper foil laminated film provided in the step (a); the plating resist pattern layer having an opening portion corresponding to the wiring pattern,
(c) carrying out copper plating on the copper foil part exposed from the opening,
(d) removing the plating resist pattern layer on the copper foil, and
(e) removing the copper foil exposed on a portion where the plating resist pattern layer has been removed, whereby exposing the polyimide film.

2. The process according to claim 1, wherein the step (a) comprises steps of:
(a-1) providing a copper foil laminated polyimide film with carrier, wherein copper foil(s) has a surface roughness Rz of 1.0 μm or less in a side laminated to a polyimide film and a thickness in the range of 1 to 8 μm,
(a-2) peeling off the carrier foil from the copper foil laminated polyimide film, and
(a-3) optionally, thinning a thickness of the copper foil to the range of 0.5 to 2 μm by etching.

3. The process according to claim 1, in which the copper foil having a thickness in the range of 0.5 to 2 μm of the step (a) is a copper foil that has been subjected to etching treatment.

4. The process according to claim 1, in which the step (b) comprises a step of forming a plating resist layer on a surface of the copper foil, a step of exposing to light through a photomask and a step of forming an opening portion of the plating resist pattern layer by development.

5. The process according to claim 1, in which the step (e) is carried out by flash etching.

6. The process according to claim 1, in which the thickness of the copper foil of the copper foil laminated polyimide film with carrier to be provided is in the range of 2 to 4 μm.

7. The process according to claim 1, in which the polyimide film constituting the copper foil laminated polyimide film with carrier that is provided is obtained by laminating and integrating thermo-compression bonding polyimide layer(s) on one side or both sides of a high heat resistant aromatic polyimide layer.

8. A copper wiring polyimide film which comprises a 20 to 45 μm-pitch copper wiring part and is produced by the process according to claim 1.

9. A copper foil laminated polyimide film with carrier, comprising a polyimide film and a copper foil with carrier directly laminated on one side or both sides of the polyimide film, wherein the copper foil has a surface roughness Rz of 1.0 μm or less in the side laminated to the polyimide film and a thickness in the range of 1 to 8 μm.

10. A copper foil laminated polyimide film, comprising a polyimide film and a copper foil with carrier directly laminated on one side or both sides of the polyimide film, wherein the copper foil has a surface roughness Rz of 1.0 μm or less in the side laminated to the polyimide film and a thickness in the range of 0.5 to 2 μm, and wherein the copper foil has been subjected to etching treatment.
